(19) United States
(12) Patent Application Publication
(10) Pub. No.: US 2008/0111622 A1
(43) Pub. Date: May 15, 2008

(54) Hybrid Doherty Amplifier System and Method

(76) Inventors: Roland Sperlich, Dallas, TX (US); Gregory Clark Copeland, Plano, TX (US); Russell Hoppenstein, Richardson, TX (US)

Correspondence Address: TEXAS INSTRUMENTS INCORPORATED, P O BOX 655474, M/S 3999, DALLAS, TX, 75265, US

(21) Appl. No.: 11/940,096

(22) Filed: Nov. 14, 2007

Related U.S. Application Data
(60) Provisional application No. 60/865,783, filed on Nov. 14, 2006.

(51) Int. Cl. H03F 3/68

(52) U.S. Cl. 330/124 R

(57) ABSTRACT

One embodiment of the invention includes an amplifier system. The system comprises a digital predistortion (DPD) system configured to receive an input signal and to provide the input signal as a first digital signal component along a first amplifier path and a second digital signal component along a second amplifier path. The system also comprises a first digital-to-analog converter (DAC) configured to convert the first digital signal component to a first analog signal component and a second DAC configured to convert the second digital signal component to a second analog signal component. The system further comprises a Doherty amplifier comprising a main amplifier in the first amplifier path that is configured to amplify the first analog signal component and a peak amplifier in the second amplifier path that is configured to amplify the second analog signal component.

### RELATED APPLICATION

The present invention claims priority from U.S. Provisional Patent Application No. 60/865,783, filed Nov. 14, 2006.

### TECHNICAL FIELD

This invention relates to electronic circuits, and more specifically to a hybrid Doherty amplifier system and method.

### BACKGROUND

Power amplifiers used for wireless communication transmitters, with spectrally efficient modulation formats, require high linearity to preserve modulation accuracy and to limit spectral regrowth. Typically, a linear amplifier such as a Class-A type, a Class-AB type, or a Class-B type is employed to faithfully reproduce input signals and to limit the amplifier output within a strict emissions mask. Linear amplifiers are capable of electrical (DC power into RF output power or DC-RF) efficiencies greater than 50% when operated at saturation. However, they are generally not operated at high efficiency due to the need to provide high linearity. For non-constant envelope waveforms, linear amplifiers are often operated below saturation to provide for operation in the linear region. The back-off level from amplifier saturation, also referred to as output power back-off (OPBO), determines the electrical efficiency of a linear amplifier.

A Doherty amplifier is an amplifier configuration that can provide significantly improved efficiency. A typical Doherty amplifier configuration includes both a main amplifier and a peak amplifier. The main amplifier receives the entirety of the input signal all of the time but is operative to output signals up to a certain saturation amplitude level. The peak amplifier shares the signal load with the main amplifier during peak level signals above the saturation amplitude level. Therefore, the peak amplifier operates only part of the time, while the main amplifier operates all of the time. Accordingly, a Doherty amplifier can provide a significantly improved efficiency at higher power levels.

While the Doherty amplifier does provide significantly improved efficiency at higher power levels, the Doherty amplifier can be inefficient at low power levels. Specifically, at times when the transmitted signal need not be amplified so much, and is thus backed-off from saturation, the Doherty amplifier can operate at a poor efficiency (e.g., as little as 8%). In addition, a typical Doherty amplifier often provides poor linearity characteristics. Specifically, the Doherty amplifier can include an asymmetrical signal splitter to split the input signal between the main amplifier and the peak amplifier, as well as input impedance matching and phase-matching circuits to ensure phase accuracy of the split signals before and after amplification. Designing the Doherty amplifier to properly set the impedances for the impedance matching circuits and the asymmetrical signal splitter to ensure phase accuracy can be difficult, particularly over a range of frequency, time, and temperature. Phase inaccuracies resulting from impedance mismatch over the range of frequency, time, and temperature can thus result in non-linear signal characteristics.

To compensate for the poor linearity of the Doherty amplifier, a typical communication system can include a digital predistortion (DPD) system. The DPD system is configured to compensate for impedance errors that can occur in the Doherty amplifier and/or other sources by applying correction factors to the signal to be amplified. However, in providing correction factors regarding one of the amplifiers (i.e., main and peak amplifiers), it is possible that linearity of the other of the amplifiers is degraded. Accordingly, compensation for the poor linearity of the Doherty amplifier with DPD can also be challenging.

### SUMMARY

One embodiment of the invention includes an amplifier system. The system comprises a digital predistortion (DPD) system configured to receive an input signal and to provide the input signal as a first digital signal component along a first amplifier path and a second digital signal component along a second amplifier path. The system also comprises a first digital-to-analog converter (DAC) configured to convert the first digital signal component to a first analog signal component and a second DAC configured to convert the second digital signal component to a second analog signal component. The system further comprises a Doherty amplifier comprising a main amplifier in the first amplifier path that is configured to amplify the first analog signal component and a peak amplifier in the second amplifier path that is configured to amplify the second analog signal component.

Another embodiment of the invention includes a method for amplifying an input signal. The method comprises providing a first digital signal component and a second digital signal component from the input signal. The method also includes providing non-linearity compensation to each of the first and second digital signal components in response to a digital feedback signal. The method also includes converting each of the first digital signal component and the second digital signal component into a first analog signal component and a second analog signal component, respectively. The method also includes providing the first analog signal component to a main amplifier of a Doherty amplifier along a first amplifier path and providing the second analog signal component to a peak amplifier of the Doherty amplifier along a second amplifier path. The method further includes amplifying and combining the first and second analog signal components to provide an analog output signal.

Another embodiment of the invention includes a amplifier system. The system comprises means for providing in programmable proportions a first digital signal component along a first programmable path and a second digital signal component along a second programmable path from a digital input signal. The system also comprises means for converting the first and second digital signal components into a first analog signal component and a second analog signal component, respectively. The system further comprises main amplifier means for amplifying the first analog signal component along the first amplifier path, peak amplifier means for amplifying the second analog signal component along the second amplifier path, and means for combining the first and second analog signal components to generate an output signal.

### BRIEF DESCRIPTION OF THE DRAWINGS

FIG. 1 illustrates an example of an amplifier system in accordance with an aspect of the invention.

FIG. 2 illustrates an example of a communication system in accordance with an aspect of the invention.

FIG. 3 illustrates an example of an amplifier chain in accordance with an aspect of the invention.

FIG. 4 illustrates an example of a method for amplifying a communication signal in accordance with an aspect of the invention.

### DETAILED DESCRIPTION

The invention relates to electronic circuits, and more specifically to a hybrid Doherty amplifier system and method. A digital predistortion (DPD) system is configured to provide a main signal component along a main amplifier path and a peak signal component along a peak amplifier path from a digital input signal. Providing the digital input signal as the main and peak signal components can be based on a programmable proportion, such as could be provided from a processor. The DPD system also performs phase and/or gain adjustments to each of the signal components. The signal components are converted to analog signals and are each provided to a Doherty amplifier. The main signal component is provided to the main amplifier of the Doherty amplifier and the peak signal component is provided to the peak amplifier of the Doherty amplifier. Thus, the main and peak amplifiers of the Doherty amplifier can amplify the signal components according to the proportions of the split input signal, and not based on a saturation condition of the main amplifier. Therefore, the Doherty amplifier can operate significantly more efficiently. Furthermore, because the signals are isolated prior to being input to the Doherty amplifier, the Doherty amplifier need not include an asymmetrical splitter, impedance matching input circuitry, and phase-matching circuitry. Accordingly, the Doherty amplifier can operate in a much more linear manner, and the design of the Doherty amplifier can be greatly simplified.

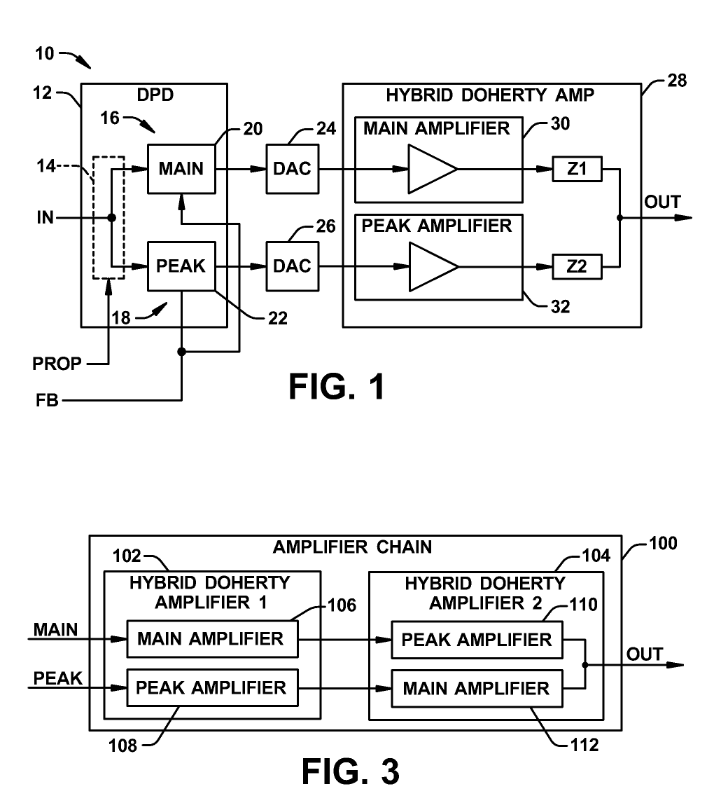

FIG. 1 illustrates an example of an amplifier system 10 in accordance with an aspect of the invention. The amplifier system 10 can be implemented in any of a variety of signal applications that require amplification of a signal. As an example, the amplifier system 10 can be implemented in a wireless or wired transmitter or receiver. Furthermore, the amplifier system 10 can be implemented in substantially any type of signal transmitter and/or receiver environments, such as heterodyne or homodyne, zero-intermediate frequency (IF) or high-IF, and real or complex transmitter/receiver environments.

The amplifier system 10 receives a digital input signal IN that is provided to a digital predistortion (DPD) system 12. The DPD system 12 includes a signal divider 14 that is configured to provide the digital input signal IN as a main digital signal component on a main amplifier path 16 and as a peak digital signal component on a peak amplifier path 18. The division of the digital input signal IN can be in response to a signal PROP that defines a programmable proportion of the division of the digital input signal IN between the main amplifier path 16 and the peak amplifier path 18. As an example, the programmable proportion can be adjusted by a processor in an adaptive manner, could be a value stored in a memory register, or could be a hard-coded firmware setting.

The DPD system 12 also includes a main predistortion element 20 and a peak predistortion element 22. The main and peak predistortion elements 20 and 22 are configured to provide individual non-linearity compensation to the main digital signal component and the peak digital signal component, respectively. As an example, the main predistortion element 20 and the peak predistortion element 22 can be configured to provide adjustments to amplitude-modulation (AM) and phase-modulation (PM) non-linearity terms, such as AM-AM and AM-PM terms, of each of the main and peak digital signal components individually. As another example, the main predistortion element 20 and the peak predistortion element 22 can provide adjustments to memory predistortion terms (i.e., time-dependent predistortion terms) as well as memory-less predistortion terms. In the example of FIG. 1, the non-linearity compensation is performed by the respective main and peak predistortion elements 20 and 22 in response to a feedback signal FB. As an example, the feedback signal FB can correspond to feedback information of an output signal OUT of the amplifier system 10.

The main digital signal component and the peak digital signal component are each output from the DPD system 12 to respective digital-to-analog converters (DACs) 24 and 26. The DACs 24 and 26 are each configured to convert the digital signal components to an analog form. Therefore, the DAC 24 is configured to convert the main digital signal component into a main analog signal component, and the DAC 26 is configured to convert the peak digital signal component into a peak analog signal component. The respective main and peak analog signal components are each provided to a hybrid Doherty amplifier 28.

The hybrid Doherty amplifier 28 includes a main amplifier 30 in the main amplifier path 16 and a peak amplifier 32 in the peak amplifier path 18. Thus, the main analog signal component is provided to the main amplifier 30 and the peak analog signal component is provided to the peak amplifier 32. As an example, the main amplifier 30 can be configured as a Class-AB amplifier and the peak amplifier 32 can be configured as a Class-C amplifier. However, it is to be understood that the main amplifier 30 and the peak amplifier 32 can instead be configured as any of a variety of other amplifier types to provide a desired combination of efficiency and linearity.

The main amplifier 30 and the peak amplifier 32 are thus respectively configured to amplify the respective main analog signal component and peak analog signal component. The amplified main and peak analog signal components are each provided to impedance matching output elements Z1 and Z2, respectively, before being combined as the output signal OUT. Therefore, the output signal OUT is an amplified analog version of the digital input signal IN having been predistorted to compensate for non-linearity that may have been introduced by the hybrid Doherty amplifier 28 and/or other sources.

Because the hybrid Doherty amplifier 28 receives the isolated main and peak analog signal components, it is to be understood that the hybrid Doherty amplifier 28 includes neither an asymmetrical signal splitter nor impedance matching input circuitry, as included in a typical Doherty amplifier. Thus, the hybrid Doherty amplifier 28 can be designed in a less complicated manner and at a reduced cost. In addition, as described above, the DPD system 12 provides non-linearity compensation to the isolated main and peak digital signal components individually via the main and peak predistortion elements 20 and 22, respectively. As a result, the hybrid Doherty amplifier 28 can also be designed without phase-matching circuitry, as the relative phase of the main and peak digital signal components can be controlled by the DPD system 12 via the main and peak predistortion elements 20 and 22. For these reasons, the hybrid Doherty amplifier 28 can exhibit significantly improved linear performance over a typical Doherty amplifier.

Furthermore, because the division of the digital input signal IN is based on a programmable proportion, the hybrid Doherty amplifier 28 can be controlled with regard to the amount of relative amplification provided at each of the main amplifier path 16 and peak amplifier path 18. Specifically, the signal divider 14 can control the relative proportion of the digital input signal IN that is amplified by each of the main amplifier 30 and the peak amplifier 32. As a result, the hybrid Doherty amplifier 28 can exhibit a significant improvement in efficiency over a typical Doherty amplifier, as peak amplifier 32 does not amplify only the portion of the signal that exceeds saturation of the main amplifier 30 while remaining idle during times of saturation back-off. Accordingly, the hybrid Doherty amplifier 28 can maximize the amplification efficiency of the main amplifier 30 and the peak amplifier 32 based on the division of the digital input signal IN in response to the programmable proportion defined by the signal PROP.

It is to be understood that the amplifier system 10 is not intended to be limited to the example of FIG. 1. As an example, depending on the type of application in which the amplifier system 10 is implemented, the amplifier system 10 can include additional interposing components, such as modulators or demodulators. In addition, the amplifier system 10 can include one or more additional amplifiers, which could include additional hybrid Doherty amplifiers, configured to provide further amplification of the digital input signal IN to generate the amplified output signal OUT. Furthermore, the hybrid Doherty amplifier 28 can include additional amplifier paths other than the main and the peak amplifier paths, with each of the paths having separate efficiency and/or linearity characteristics. As an example, the DPD system 12 can divide the input signal IN into three or more analog signal components that are each provided on a separate and isolated amplifier path, such that each of the three or more analog signal components receives separate non-linearity compensation and separate amplification in the Doherty amplifier before recombination as the output signal OUT. Accordingly, the amplifier system 10 can be configured in any of a variety of ways.

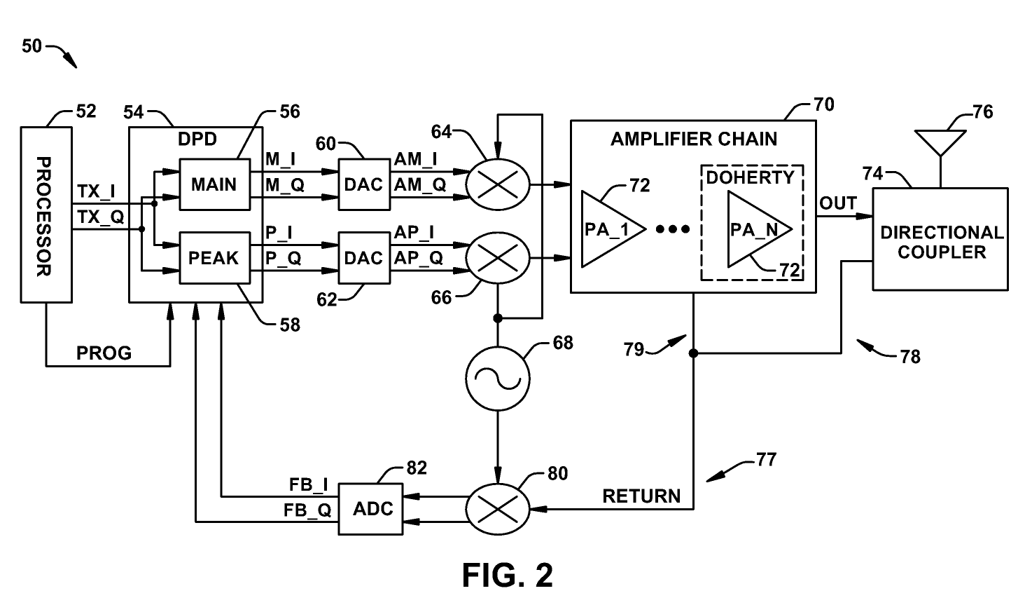

FIG. 2 illustrates an example of a communication system 50 in accordance with an aspect of the invention. The communication system 50 can be implemented in any of a variety of communication devices, such as a portable telephone or a wireless modem. The communication system 50 includes a processor 52 that is configured to generate a transmit signal TX for transmission. As an example, the processor 52 can be configured to perform digital upconversion and/or crest-factor reduction on the transmit signal TX, such as to reduce a peak-to-average ratio (PAR) of the transmit signal TX. In addition, the example of FIG. 1 demonstrates that the transmit signal TX is modulated into I- and Q-components. The I- and Q-components, demonstrated in the example of FIG. 1 as TX_I and TX_Q, can collectively form an information-carrying baseband signal that has been upconverted into a stream of digital samples. It is to be understood, however, that the transmit signal TX is not limited to being modulated into the respective I- and Q-components, but could instead be modulated into amplitude and phase components, or could be a single-ended signal.

The transmit signal TX_I and TX_Q is provided to a DPD system 54. The DPD system 54 is configured substantially similar to the DPD system 12 in the example of FIG. 1. Specifically, the DPD system 54 is configured to provide main and peak components of the transmit signal TX_I and TX_Q onto respective main and peak amplifier paths based on a signal PROP that defines a programmable proportion of division. The DPD system 54 can also be configured to compensate for non-linearity of the respective main and peak components of the transmit signal TX_I and TX_Q. Specifically, a main predistortion element 56 and a peak predistortion element 58 can adjust non-linear terms of the individual main and peak components of the transmit signal TX_I and TX_Q, respectively, to generate main digital signal components M_I and M_Q and peak digital signal components P_I and P_Q.

The main digital signal components M_I and M_Q are provided to a DAC 60, and the peak digital signal components P_I and P_Q are provided to a DAC 62. The DAC 60 is configured to convert the main digital signal components M_I and M_Q into main analog signal components AM_I and AM_Q. Likewise, the DAC 62 is configured to convert the peak digital signal components P_I and P_Q into a peak analog signal components AP_I and AP_Q. The main analog signal components AM_I and AM_Q are provided to a mixer 64, and the peak analog signal components AP_I and AP_Q are provided to a mixer 66. The mixers 64 and 66 are each configured to modulate the respective main and peak analog signal components AM_I and AM_Q and AP_I and AP_Q based on a local oscillator (LO) signal that is generated by a LO 68.

The resultant modulated main and peak signals are provided to an amplifier chain 70. The amplifier chain 70 includes a plurality N power amplifier stages 72, demonstrated in the example of FIG. 2 as PA_1 through PA_N, where N is a positive integer. Each of the power amplifier stages 72 are configured in series with respect to each other can include a separate power amplifier pair configured to amplify each of the main and peak signals by a respective amount of gain. As an example, each of the power amplifier stages 72 can have a gain of approximately 12-15 dB, such that the resultant output signal from the amplifier chain 70 can have a large gain based on the successive amplification of the power amplifier stages 72.

The last of the power amplifier stages in the sequential amplifier chain 70, PA_N, can be configured as a hybrid Doherty amplifier, similar to the hybrid Doherty amplifier 28 in the example of FIG. 1. Therefore, the power amplifier PA_N can include a main amplifier in the main amplifier path and a peak amplifier in the peak amplifier path. Thus, the modulated main analog signal component is amplified by the main amplifier and the modulated peak analog signal component is amplified by the peak amplifier. The amplified main and peak analog signal components can each provided to impedance matching output elements to be combined as the output signal OUT, similar to as described above in the example of FIG. 1. Therefore, the output signal OUT is an amplified analog version of the transmit signal TX having been predistorted to compensate for non-linearity. The output signal OUT is thus provided to a directional coupler 74. As an example, the directional coupler 74 can provide a coupled signal for feedback, as described below. The output of the directional coupler 74 is transmitted via an antenna 76.

It is to be understood that the amplifier chain 70 is not intended to be limited to the single hybrid Doherty amplifier PA_N. FIG. 3 illustrates an example of an amplifier chain 100 in accordance with an aspect of the invention. As an example, the amplifier chain 100 can be implemented in the communication system 50 in the example of FIG. 2. The amplifier chain 100 includes a first hybrid Doherty amplifier 102 and a second hybrid Doherty amplifier 104. The first hybrid Doherty amplifier 102 includes a main amplifier 106 that is configured in the main amplifier path, demonstrated as MAIN in the example of FIG. 3, and a peak amplifier 108 that is configured in the peak amplifier path, demonstrated as PEAK in the example of FIG. 3. As an example, the main amplifier 106 can be configured as a Class-AB amplifier and the peak amplifier 108 can be configured as a Class-C amplifier. Thus, the first hybrid Doherty amplifier 102 is configured substantially similar to the hybrid Doherty amplifier 28 in the example of FIG. 1, such that the main analog signal component is amplified by the main amplifier 106 and the peak analog signal component is amplified by the peak amplifier 108.

The second hybrid Doherty amplifier 104 includes a main amplifier 110 and a peak amplifier 112. Similar to the first hybrid Doherty amplifier 102, the main amplifier 110 can be configured as a Class-AB amplifier and the peak amplifier 112 can be configured as a Class-C amplifier. However, the main amplifier 110 is configured in the peak amplifier path PEAK, and the peak amplifier 112 is configured in the main amplifier path MAIN. As a result, the main analog signal component is amplified first by the main amplifier 106 in the first hybrid Doherty amplifier 102, followed by the peak amplifier 112 in the second hybrid Doherty amplifier 104. Similarly, the peak analog signal component is amplified first by the peak amplifier 108 in the first hybrid Doherty amplifier 102, followed by the main amplifier 110 in the second hybrid Doherty amplifier 104. As a result, the efficiency and the linearity of the amplifier chain 100, and thus the entire amplifier system in which the amplifier chain 100 is included, can be even further improved by sequentially providing both main and peak amplification to each of the main and peak analog signal components. The main and peak analog signal components are combined in the second hybrid Doherty amplifier 104, such as via impedance matching output circuitry (not shown), and provided as the output signal OUT.

It is to be understood that the amplifier chain 100 is not limited to the example of FIG. 3. Specifically, the amplifier chain 100 can include additional power amplifiers that are configured in series with the first and second hybrid Doherty amplifiers 102 and 104 in each of the main amplifier path MAIN and the peak amplifier path PEAK. Furthermore, any or all of the additional power amplifiers can also be configured as hybrid Doherty amplifiers, such that the main and peak analog signal components can each be provided to separate main and/or peak amplifiers in each of the sequential hybrid Doherty amplifiers in any of a variety of combinations. Accordingly, the amplifier chain 100 can be configured in any of a variety of ways.

Referring back to the example of FIG. 2, the communication system 50 includes a feedback path 77 that includes a signal RETURN being provided from the amplifier chain 70. As an example, the signal RETURN can be associated with or can include the output signal OUT, such that it can be a coupled signal provided from the directional coupler 74, indicated in the example of FIG. 2 at 78. As another example, the signal RETURN can include one or more signals that are associated with respective individual amplified main and peak analog signal components from one or more of the power amplifier stages 72, indicated in the example of FIG. 2 at 79. For example, the amplifier chain 70 can include an RF switch (not shown) to select a given source of feedback to be provided on the signal RETURN at a given time.

The signal RETURN is provided to a mixer 80 that is configured to demodulate the signal RETURN based on the LO signal that is generated by the LO 68. The resultant demodulated signal can be separated into respective I- and Q-components, which are provided to an analog-to-digital converter (ADC) 82. The ADC 82 is configured to convert the demodulated signal into a digital form to generate a feedback signal FB_I and FB_Q.

The feedback signal FB_I and FB_Q is provided to the DPD system 54 to provide feedback information associated with the linearity of the output signal OUT and/or one or more of the power amplifier stages 72. Thus, the signal RETURN can include information regarding the amplification, and thus possible non-linearity, of the main and peak amplifier paths for any or all of the power amplifier stages 72, including the hybrid Doherty amplifier of the final stage 72. The DPD system 54 can thus be configured to control the main predistortion element 56 and the peak predistortion element 58 in response to the feedback signal FB_I and FB_Q.

As an example, the inphase feedback component FB_I can be implemented by the DPD system 54 to perform amplitude and/or phase adjustments to one or both of the main digital signal component and the peak digital signal component. As another example, the quadrature-phase feedback component FB_Q can be implemented by the DPD system 54 to perform amplitude and/or phase adjustments to the peak digital signal component. As a result, the DPD system 54 can compensate for non-linearity of the output signal OUT based on the feedback signal FB_I and FB_Q. The compensation can be adaptive, such that the DPD system 54 continuously monitors the feedback signal FB_I and FB_Q to perform non-linearity compensation. As another example, the compensation can be periodically performed, such as in response to a training sequence in which a series of training signals are periodically transmitted from the communication system 50 for the purpose of compensating for non-linearity of the output signal OUT.

Based on the above described configuration, the communication system 50 can effectively amplify and transmit the transmit signal TX in an efficient and linear manner. Specifically, the division of the transmit signal TX in the DPD system 54 in the programmable proportion, as well as the non-linear compensation of the main and peak analog signal components in response to the feedback signal FB_I and FB_Q, provides for a more efficient and linear operation of the at least one hybrid Doherty amplifier 72 in the amplifier chain 70. Furthermore, the division of the transmit signal TX in the DPD system 54 in the programmable proportion provides for a less complex and less cost-intensive design of the hybrid Doherty amplifier 72. As a result, the communication system 50 can likewise be employed at a reduced cost.

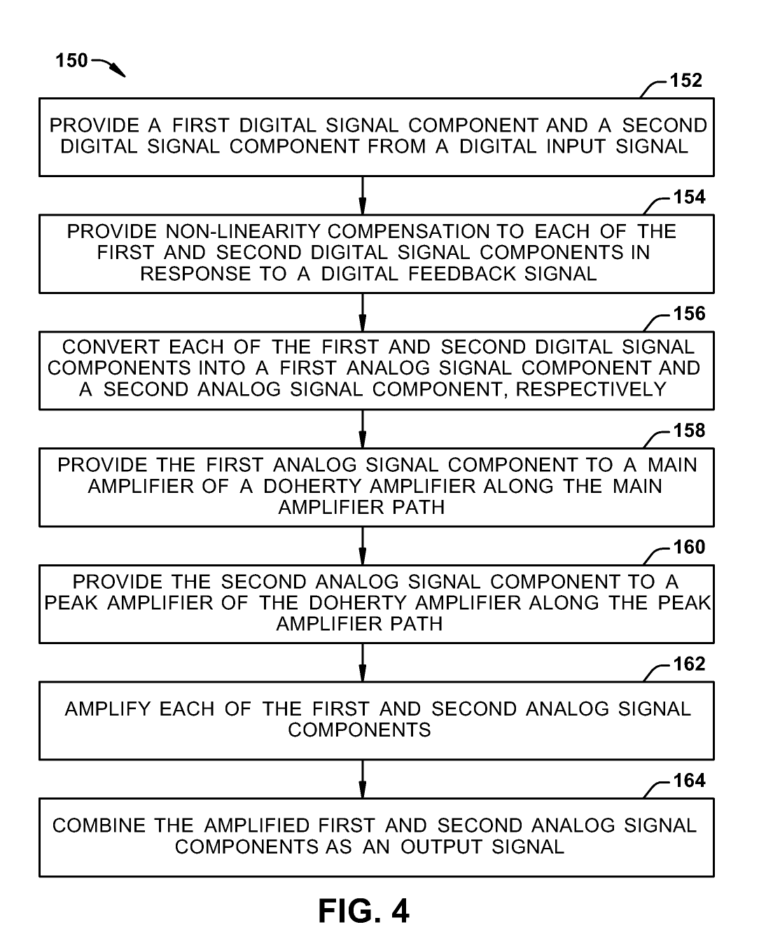

In view of the foregoing structural and functional features described above, certain methods will be better appreciated with reference to FIG. 4. It is to be understood and appreciated that the illustrated actions, in other embodiments, may occur in different orders and/or concurrently with other actions. Moreover, not all illustrated features may be required to implement a method. It is to be further understood that the following methodologies can be implemented in hardware (e.g., analog or digital circuitry, such as may be embodied in an application specific integrated circuit), software (e.g., as executable instructions stored in memory or running on one or more computer systems or a DSP), or any combination of hardware and software.

FIG. 4 illustrates an example of a method 150 for amplifying a communication signal in accordance with an aspect of the invention. At 152, a first digital signal component and a second digital signal component are provided from a digital input signal. The division of the first and second digital signal components can be based on a programmable proportion. The first digital signal component can be a main signal component in a main amplifier path, and the second digital signal component can be a peak signal component in a peak amplifier path. At 154, non-linearity compensation can be provided to each of the first and second digital signal components in response to a digital feedback signal. The digital feedback signal can be associated with the output signal or one or more power amplifiers in each of the main and/or peak amplifier paths, and can carry information regarding the linearity of each of the main amplifier path and the peak amplifier path. The non-linearity compensation can be adjustments to memory and memory-less amplitude and/or phase non-linearity terms.

At 156, each of the first digital signal component and the second digital signal component are converted into a first analog signal component and a second analog signal component, respectively. The conversion can be based on the operation of a separate DAC in each of the main amplifier path and peak amplifier path. At 158, the first analog signal component is provided to a main amplifier of a Doherty amplifier along the main amplifier path. The main amplifier can be a Class-AB amplifier. At 160, the second analog signal component is provided to a peak amplifier of the Doherty amplifier along the peak amplifier path. The peak amplifier can be a Class-C amplifier.

At 162, each of the first and second analog signal components are amplified. Each of the first and second analog signal components can also be amplified by additional power amplifiers upstream of the Doherty amplifier. One or more of the additional power amplifiers can include additional Doherty amplifiers. At 164, the amplified first and second analog signal components are combined as an output signal. The combination of the first and second signal components can be based on an impedance matching output circuit in the Doherty amplifier. The output signal can have been modulated, such that it can be transmitted.

What have been described above are examples of the invention. It is, of course, not possible to describe every conceivable combination of components or methodologies for purposes of describing the invention, but one of ordinary skill in the art will recognize that many further combinations and permutations of the invention are possible. Accordingly, the invention is intended to embrace all such alterations, modifications, and variations that fall within the scope of this application, including the appended claims.

What is claimed is:

1. An amplifier system comprising:
a digital predistortion (DPD) system configured to receive an input signal and to provide the input signal as a first digital signal component along a first amplifier path and a second digital signal component along a second amplifier path;
a first digital-to-analog converter (DAC) configured to convert the first digital signal component to a first analog signal component;
a second DAC configured to convert the second digital signal component to a second analog signal component; and
a Doherty amplifier comprising a main amplifier in the first amplifier path that is configured to amplify the first analog signal component and a peak amplifier in the second amplifier path that is configured to amplify the second analog signal component.

2. The system of claim 1, wherein the main amplifier is a Class-AB amplifier and the peak amplifier is a Class-C amplifier.

3. The system of claim 1, wherein the DPD system is configured to provide the input signal as the first and second digital signal components in a programmable proportion relative to each other.

4. The system of claim 1, wherein the Doherty amplifier is further configured to combine the amplified first and second analog signal components into an output signal.

5. The system of claim 1, wherein the DPD system is further configured to provide adjustments to non-linear terms associated with each of the first and second digital signal components individually.

6. The system of claim 1, further comprising at least one additional amplifier arranged in series with the Doherty amplifier, the at least one additional amplifier being configured to amplify the first analog signal component and the second analog signal component.

7. The system of claim 6, wherein the DPD system is configured to provide adjustments to non-linear terms in response to a feedback signal that is associated with at least one of the at least one amplifier and the Doherty amplifier.

8. The system of claim 1, wherein the Doherty amplifier is a first Doherty amplifier, the system further comprising a second Doherty amplifier arranged in series with the first Doherty amplifier, the second Doherty amplifier comprising a second main amplifier configured to amplify the second analog signal component and a second peak amplifier configured to amplify the first analog signal component.

9. The system of claim 1, wherein each of the first digital signal component and the second digital signal component comprises an inphase (I) component and a quadrature-phase (Q) component.

10. A communication system comprising the amplifier system of claim 1.

11. A method for amplifying an input signal, the method comprising:
providing a first digital signal component and a second digital signal component from the input signal;
providing non-linearity compensation to each of the first and second digital signal components in response to a digital feedback signal;
converting each of the first digital signal component and the second digital signal component into a first analog signal component and a second analog signal component, respectively;
providing the first analog signal component to a main amplifier of a Doherty amplifier along a first amplifier path;
providing the second analog signal component to a peak amplifier of the Doherty amplifier along a second amplifier path; and
amplifying and combining the first and second analog signal components to provide an analog output signal.

12. The method of claim 11, wherein splitting the communication signal comprises:
allocating a first portion of the communication signal as the first digital signal component and allocating a second portion of the communication signal as the second digital signal component based on a programmable proportion.

13. The method of claim 11, further comprising providing separate feedback information associated with the first amplifier path and the second amplifier path as the digital feedback signal.

14. The method of claim 11, wherein providing non-linearity compensation comprises providing adjustments to non-linear terms associated with each of the first and second digital signal components individually.

15. The method of claim 11, further comprising:
providing the first and second analog signal components to at least one additional amplifier arranged upstream and in series with the Doherty amplifier;
amplifying the first and second analog signal components prior to providing the first and second analog signal components to the main amplifier and the peak amplifier, respectively, of the Doherty amplifier; and
transmitting the analog output signal.

16. The method of claim 11, wherein the Doherty amplifier is a first Doherty amplifier, the method further comprising:
providing the amplified first analog signal component to a second peak amplifier of a second Doherty amplifier;
providing the amplified second analog signal component to a second main amplifier of the second Doherty amplifier; and
amplifying the amplified first and second analog signal components.

17. An amplifier system comprising:
means for providing in programmable proportions a first digital signal component along a first programmable path and a second digital signal component along a second programmable path from a digital input signal;
means for converting the first and second digital signal components into a first analog signal component and a second analog signal component, respectively;
main amplifier means for amplifying the first analog signal component along the first amplifier path;
peak amplifier means for amplifying the second analog signal component along the second amplifier path; and
means for combining the first and second analog signal components to generate an output signal.

18. The system of claim 17, further comprising means for generating a digital feedback signal based on the first amplifier path and the second amplifier path, the system further comprising means for providing non-linearity compensation to each of the first and second digital signal components in response to the digital feedback signal.

19. The system of claim 18, wherein the means for providing non-linearity compensation comprises means for providing adjustments to non-linear terms associated with each of the first and second digital signal components individually.

20. The system of claim 17, further comprising at least one additional means for further amplifying each of the first and second analog signal components and means for transmitting the output signal.
